(19) United States
(12) Patent Application Publication
(10) Pub. No.: US 2025/0287551 A1
(43) Pub. Date: Sep. 11, 2025

(54) METHOD OF STARTING SERVER AT LOW TEMPERATURE AND SERVER THEREOF

(71) Applicant: Fulian Precision Electronics (Tianjin) Co., LTD., Tianjin (CN)

(72) Inventor: MING-HUNG CHUNG, New Taipei (TW)

(21) Appl. No.: 18/795,397

(22) Filed: Aug. 6, 2024

(30) Foreign Application Priority Data
Mar. 7, 2024 (CN) 202410258482.4

(51) Int. Cl. H05K 7/20

(52) U.S. Cl. CPC H05K 7/20836; H05K 7/20518

(57) ABSTRACT

A method of starting a server at a low temperature is provided. The server includes N first components, N heaters, and M second components. Each heater is disposed in one of the first components. A lowest starting temperature of each first component is higher than a lowest starting temperature of each second component. In the method, a first temperature of each first component and a second temperature of each second component are obtained in real-time. The N heaters are turned on for a predetermined time duration when it is determined that at least one of the first temperatures and the second temperatures is less than a first predefined temperature. The N heaters are turned off after the predefined time duration. The N first components and the M second components are started after the N heaters are turned off. A server is also provided.

### TECHNICAL FIELD

The present application generally relates to computer technology, and particularly to a method of starting a server at low temperature and a server thereof.

### BACKGROUND

Servers usually operates at a low temperature environment, in a range from −5 C.° to −40 C.°. Some components in the server operated at the low temperature environment may present a starting problem, that is, the component is unable to start to work at the low temperature environment. Thus, a performance of the server is affected.

There is room for improvement in the art.

### BRIEF DESCRIPTION OF THE DRAWINGS

Implementations of the present application will now be described, by way of example only, with reference to the attached figures.

FIG. 1 is a diagram illustrating an embodiment of a server according to the present application.

FIG. 2 is a flowchart illustrating a first embodiment of a method of starting the server at a low temperature according to the present application.

FIG. 3 is a flowchart illustrating a second embodiment of a method of starting the server at a low temperature according to the present application.

FIG. 4 is a flowchart illustrating a third embodiment of a method of starting the server at a low temperature according to the present application.

FIG. 5 is a flowchart illustrating a fourth embodiment of a method of starting the server at a low temperature according to the present application.

FIG. 6 is a flowchart illustrating a fifth embodiment of a method of starting the server at a low temperature according to the present application.

### DETAILED DESCRIPTION

The technical solutions in the embodiments of the present application will be clearly and completely described below which combine with reference to the accompanying drawings in the embodiments of the present application. Apparently, the described embodiments are some of the embodiments of the present application rather than all of the embodiments. Based on the embodiments of the present application, it is understandable to a person skilled in the art, any other embodiments obtained by persons skilled in the art without creative effort shall all fall into the scope of the present application. It will be understood that the specific embodiments described herein are merely some embodiments and not all.

In general, the word “module,” as used herein, refers to logic embodied in hardware or firmware, or to a collection of software instructions, written in a programming language, for example, Java, C, or assembly. One or more software instructions in the modules may be embedded in firmware, such as an EPROM, magnetic, or optical drives. It will be appreciated that modules may comprise connected logic units, such as gates and flip-flops, and may comprise programmable units, such as programmable gate arrays or processors, such as a CPU. The modules described herein may be implemented as either software and/or hardware modules and may be stored in any type of computer-readable medium or other computer storage systems. The term “comprising” means “including, but not necessarily limited to”; it specifically indicates open-ended inclusion or membership in a so-described combination, group, series, and the like. The application is illustrated by way of example and not by way of limitation in the figures of the accompanying drawings in which like references indicate similar elements. It should be noted that references to “an” or “one” embodiment in this application are not necessarily to the same embodiment, and such references can mean “at least one.”

It should be understood that, in this application, “at least one” means one or more, and “a plurality of” means two or more. The term “and/or” is used to describe an association relationship for describing associated objects, and indicates that three relationships may exist. For example, “A and/or B” may represent the following three cases: Only A exists, only B exists, and both A and B exist, where A and B may be singular or plural. Terms “first”, “second”, and the like used in the specification, the claims, and the accompanying drawings of the present application are used to distinguish different objects rather than describe a particular order.

It should be understood that the method or the method shown in a flowchart disclosed of the application includes one or more steps. The steps of the method may be interchangeably performed, without departing from the scope of the claims, and some steps may be deleted.

Servers usually operates at a low temperature environment, such as the low temperature is in a range from −5 C.° to −40 C.°. Some components in the sever operated at the low temperature environment may exist a starting problem, which is unable to start to work at the low temperature environment. Thus, a performance of the server is affected.

The present application provides a method of starting a server at a low temperature and a server, which avoids components in the server from being failure to start to work during the server operates under a low temperature environment. Therefore, a performance of the server will not be affected by the low temperature.

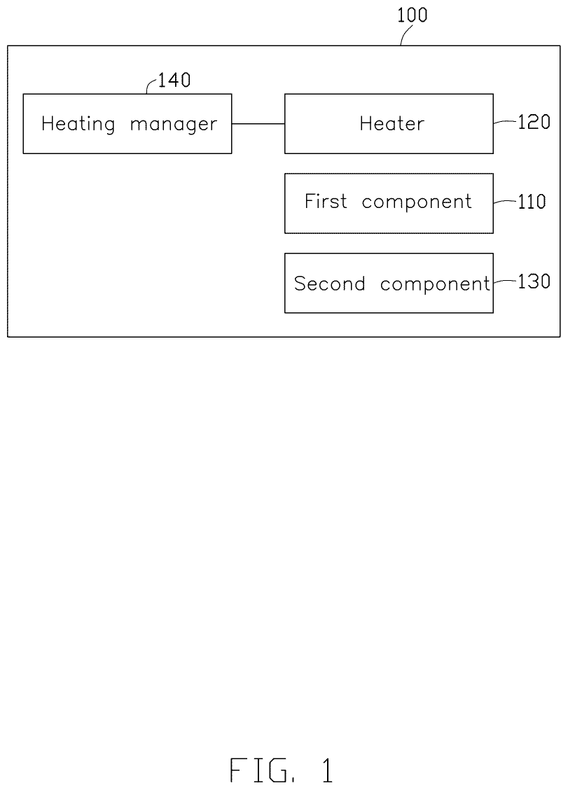

Referring to FIG. 1, FIG. 1 shows a diagram of an embodiment of a server 100 according to an embodiment of the application. The server 100 includes N first components 110, N heaters 120, and M second components 130. N and M are integer, which are larger than 1. Each heater 120 is disposed in one of the first components 110, a lowest starting temperature of each first component 110 is higher than a lowest starting temperature of each second component 130.

In one embodiment, the first component 110 may include at least one of a central processing unit (CPU), a Complex Programmable Logic Device (CPLD), a Platform Controller Hub (PCH), a Local Area Network (LAN) interface, and a Baseboard Management Controller (BMC), and the like. The second component 130 may include a display port (DP) interface, a clock buffer, a Universal Serial Bus (USB) to Universal Asynchronous Receiver-transmitter (UART) circuit, and micro-processor, and the like.

In some embodiments, the above heater 120 incudes a heating gasket and a transistor. The heating gasket is disposed on the corresponding first component 110, and is electrically connected to a heating power supply through the transistor. By controlling the turning-on of the transistor and the turning-on frequency of the transistor, a state and a heating efficiency of the heating gasket is controlled, and thus a heating process of the corresponding first component 110 is controlled. The heating power supply may be a system power supply of the server 100, or another power supply independent from the system power supply, which is only used for driving the heater 120.

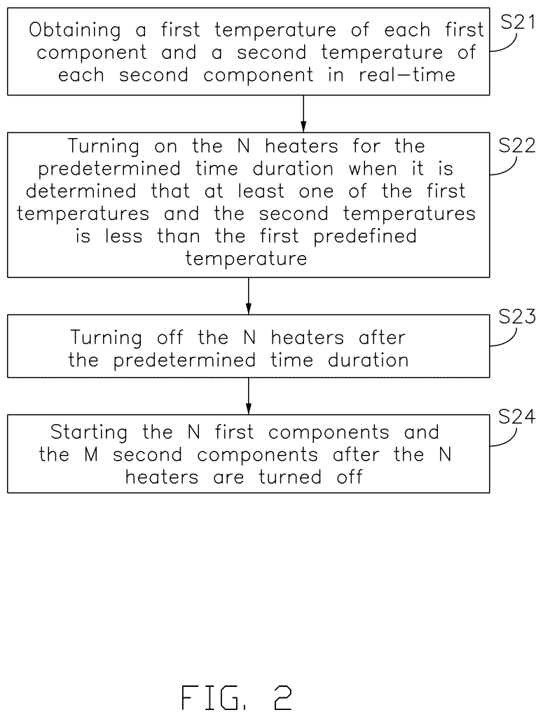

Next, referring to FIG. 2, FIG. 2 shows a first embodiment of the method of starting the server 100 at a low temperature will be described. The method includes following steps.

In block S21, a first temperature of each first component and a second temperature of each second component are obtained in real-time.

In one embodiment, the server 100 may include a heating manager 140, which is used to implement the method of starting the server 100 at a low temperature. It is understood that the heating manager 140 may include a processor being normally operated under the lower temperature environment, such as a low temperature microprocessor, and the like, not being limited to.

A starting priority of the heating manager 140 is higher than other components of the server 100. When starting the server 100, the heating manager 140 is firstly started, and after a heating logic of the heating manager 140 is successfully completed, the other components of the server 100 may be started. After being started, the heat manger obtains the first temperature of each first component and the second temperature of each second component in time.

For example, a temperature sensor is disposed on each component of the server 100. The heating manager 140 is electrically connected with the temperature sensors for obtaining the first temperatures of the first components and the second temperatures of the second components.

In block S22, the N heaters 120 are turned on for a predetermined time duration when it is determined that at least one of the first temperatures and the second temperatures is less than a first predefined temperature.

In one embodiment, after the first temperature of each first component and the second temperature of each second component are obtained by the heater manager, the first temperatures and the second temperatures are monitored for determining whether at least one of the first temperatures and the second temperatures is less than the first predefined temperature. The heating manager 140 controls all the heaters 120 to turn on for the predetermined time duration when at least one of the first temperatures and the second temperatures is less than the first predefined temperature. The heaters 120 are turned on based on a predefined power.

The heating manager 140 and the heaters 120 may be connected with an independent heating power supply, and the heating manager 140 may control the heating power supply to drive the heater 120 to work. The first predefined temperature may be a temperature in a range from −5° C. to 5° C.

In block S23, the N heaters 120 are turned off after the predefined time duration.

In block S24, the N first components 110 and the M second components 130 are started after the N heaters 120 are turned off.

It is understood that the components in the server 100 is divided into the first component 110 with a first low starting temperature and the second components 130 with a second starting temperature, and the first low starting temperature is higher than the second low starting temperature. Each first component 110 is set with the heater 120. Before starting the server 100, when at least one of the first temperatures of the first components 110 is less than the first predefined temperature, the N heaters 120 are turned on for heating the first component 110 for the predefined time duration, thus the first temperature of each first component 110 reaches the lowest starting temperature, and the second temperature of each second component 130 is within an operation temperature range without being effected by the heating operation. Therefore, it avoids that the components in the server 100 are unable to start to work, and the performance of the server 100 is not affected by the low temperature.

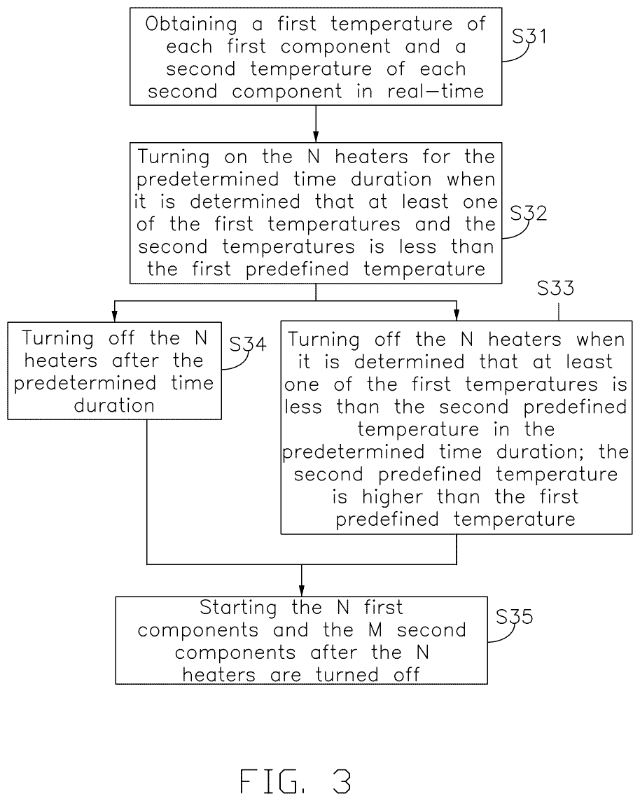

Referring to FIG. 3, FIG. 3 shows a second embodiment of the method of starting the server 100 at a low temperature will be described. The method includes following steps.

In block S31, a first temperature of each first component and a second temperature of each second component are obtained in time.

In block S32, the N heaters 120 are turned on for a predetermined time duration when it is determined that at least one of the first temperatures and the second temperatures is less than a first predefined temperature.

In block S33, the N heaters 120 are turned off when it is determined that any of the first temperatures is higher than a second predefined temperature in the predefined time duration. The second predefined temperature is higher than the first predefined temperature.

In block S34, the N heaters 120 are turned off after the predefined time duration.

In block S35, the N first components 110 and the M second components 130 are started after the N heaters 120 are turned off.

It is understood that, in second embodiment, when turning on the heaters 120 to heat the first components 110 for the predefined time duration, the heating manger further monitors whether the real-time first temperature of each first component 110 is higher than the second predefined temperature. When it is determined that the real-time first temperature of the first component 110 is higher than the second predefined temperature, the corresponding heater 120 is turned off, an excessive heating of the first component 110 is avoided. The second predefined temperature is higher than the first predefined temperature, and the second predefined temperature may be a highest operation temperature in all of the first components 110.

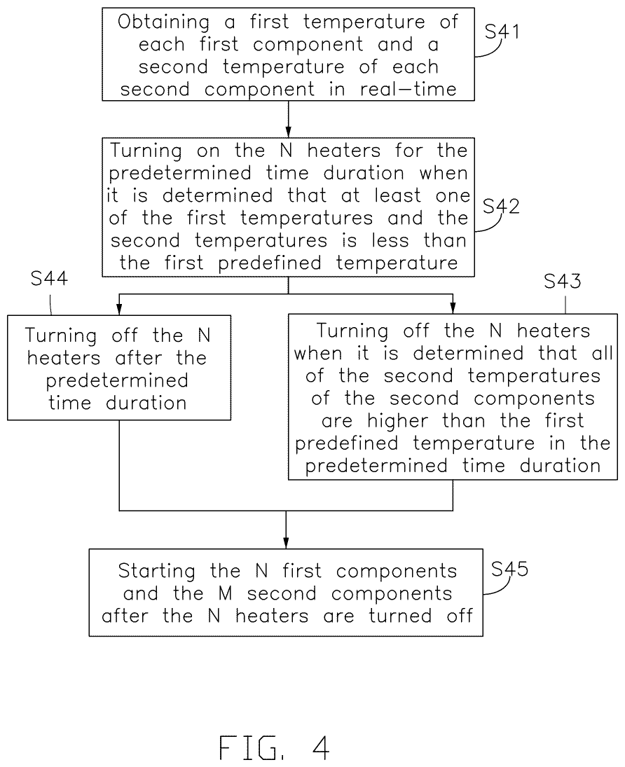

Referring to FIG. 4, FIG. 4 shows a third embodiment of the method of starting the server 100 at a low temperature will be described. The method includes following steps.

In block S41, a first temperature of each first component and a second temperature of each second component are obtained in time.

In block S42, the N heaters 120 are turned on for a predetermined time duration when it is determined that at least one of the first temperatures and the second temperatures is less than a first predefined temperature.

In block S43, the N heaters 120 are turned off when it is determined that all of the second temperatures are higher than the first predefined temperature in the predefined time duration.

In block S44, the N heaters 120 are turned off after the predefined time duration.

In block S45, the N first components 110 and the M second components 130 are started after the N heaters 120 are turned off.

It is understood that, in the third embodiment, when turning on the heaters 120 to heat the first components 110 for the predefined time duration, due to the second component 120 is capable of operating at the real-time starting temperature being lower than the first low starting temperature of the first component 110, thus the heating manager 140 may obtain the second temperatures of the second components 130 for monitoring whether the real-time temperature of each second component 130 is higher than the first predefined temperature. When the real-time temperature of each second component 130 is higher than the first predefined temperature, it is determined that the heating operation of the first components 110 are completed, and the heating manger controls the heaters 120 to be turned off, and an excessive heating of the first component 110 is avoided.

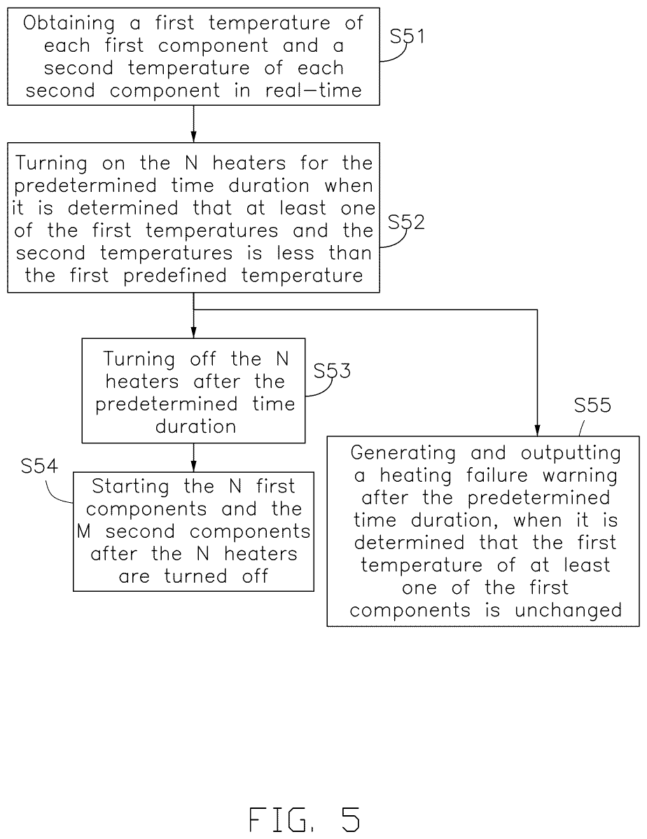

Referring to FIG. 5, FIG. 5 shows a fourth embodiment of the method of starting the server 100 at a low temperature will be described. The method includes following steps.

In block S51, a first temperature of each first component and a second temperature of each second component are obtained in time.

In block S32, the N heaters 120 are turned on for a predetermined time duration when it is determined that at least one of the first temperatures and the second temperatures is less than a first predefined temperature.

In block S53, the N heaters 120 are turned off after the predefined time duration.

In block S54, the N first components 110 and the M second components 130 are started after the N heaters 120 are turned off.

In block S55, a heating failure warning is generated and outputted when the first temperature of at least one of the first components 110 is unchanged after the predefined time duration.

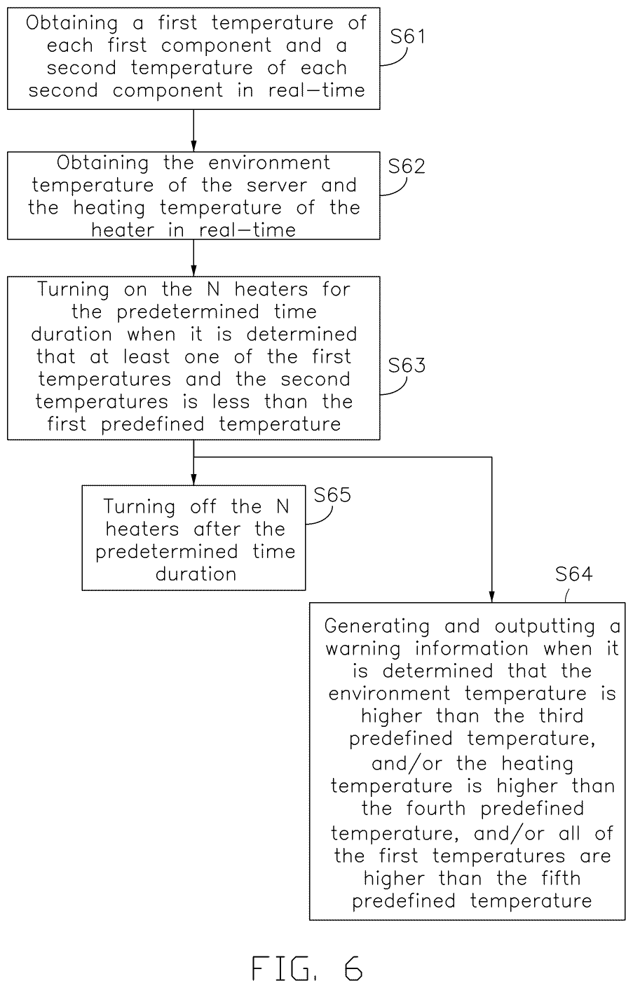

Referring to FIG. 6, FIG. 6 shows a fifth embodiment of the method of starting the server 100 at a low temperature will be described. The method includes following steps.

In block S61, a first temperature of each first component and a second temperature of each second component are obtained in time.

In block S62, an environment temperature of the server 100 and a heating temperature of each heater 120 is obtained in real-time.

In block S63, the N heaters 120 are turned on for a predetermined time duration when it is determined that at least one of the first temperatures and the second temperatures is less than a first predefined temperature.

In block S64, a warning information is generated and outputted when the environment temperature is higher than a third predefined temperature, and/or the heating temperature of the heater 102 is higher than a fourth predefined temperature, and/or all the first temperatures is higher than a fifth predefined temperature.

The third predefined temperature is higher than the first predefined temperature and is lower than the fourth predefined temperature. The fourth predefined temperature is higher than the second predefined temperature. The fifth predefined temperature is higher than the first predefined temperature and is lower than the third predefined temperature.

In block S65, the N heaters 120 are turned off after the predefined time duration.

The present application also provides a server 100 including N first components 110, N heaters 120, M second components 130, and a heating manager. N and M are integer, which are larger than 1. Each heater 120 is disposed in the first component 110, a lowest starting temperature of each first component 110 is higher than a lowest starting temperature of each second component 130. The heating manager 140 is electrically connected with the heaters 120, the first components 110, and the second components 130.

The heating manager 140 is configured to obtain the first temperature of each first component 110 and the second temperature of each second component 130, turn on the N heaters 120 when it is determined that at least one of the first temperatures and the second temperatures is less than a first predefined temperature, turn off the N heaters 120 after the predefined time duration, and turn on the N first components 110 and the M second components 130 after the N heaters 120 being turned off.

The heating manager 140 is further configured to turn off the N heaters 120 when it is determined that any of the first temperatures is higher than a second predefined temperature in the predefined time duration. The second predefined temperature is higher than the first predefined temperature.

The heating manager 140 is further configured to turn off the N heaters 120 when it is determined that all of the second temperatures are higher than the first predefined temperature in the predefined time duration.

It is understood that the beneficial effect of the server 100 of the present disclosure can refer to the detailed description of the method. Details are not described herein again.

The present application also provides a computer readable storage medium. The computer readable storage medium stores computer programs or codes, when being executed to perform the foregoing method of starting the server 100 at a low temperature.

The above embodiments may be fully or partially implemented through software, hardware, firmware or any combination thereof. When the embodiments are fully or partially implemented in the form of a computer program product, the computer program product includes one or more computer instructions. When the computer program instructions are loaded or executed on the computer, the process or function described in accordance with the embodiments of the present application is fully or partially generated. The computer may be a general purpose computer, a special purpose computer, a computer network, or other programmable device. The computer instructions can be stored in a computer readable storage medium, or transmit from a computer readable storage medium to another computer readable storage medium. For example, the computer instructions can be transmitted from a web site, computer, server, or data center through the cable (such as a coaxial cable, optical fiber, digital subscriber line (DSL)) or wireless (such as infrared, radio, microwave, etc.) to another web site, computer, server, or data center. The computer readable storage medium may be any available medium that the computer can access, or a data storage device that contains a server, a data center and the like that is integrated by one or more available medias. The available media may be magnetic media (for example, floppy disk, hard disk, magnetic tape), optical media (for example, DVD), or semiconductor media (for example, Solid State Disk (SSD)).

A person of ordinary skill in the art may understand that all or some of the processes of the methods in the embodiments may be implemented by a computer program instructing relevant hardware. The program may be stored in a computer readable storage medium. When the program runs, the processes of the methods in the embodiments are performed. The foregoing storage medium includes: any medium that can store program code, such as a ROM, a RAM, a magnetic disk, or an optical disc. If there is no conflict, the technical features in embodiments and implementations of this application may be randomly combined.

Those skilled in the art will recognize that the above described embodiments are only intended to illustrate the invention and are not intended to limit the invention, and numerous possible modifications and variations within the spirit of the invention will fall within the scope of the invention.

What is claimed is:

1. A method of starting a server at a low temperature, wherein the server comprises N first components, N heaters, and M second components; N and M are integer larger than 1; each of the N heaters is disposed in a corresponding one of the N first components, a lowest starting temperature of each of the N first components is higher than a lowest starting temperature of each of the M second components; the method comprises:
obtaining a first temperature of each of the N first components and a second temperature of each of the M second components in real-time;
turning on the N heaters for a predetermined time duration when at least one of the first temperatures and the second temperatures is determined to be less than a first predefined temperature;
turning off the N heaters after the predefined time duration; and
starting the N first components and the M second components after the N heaters are turned off.

2. The method of claim 1, wherein the method further comprises:
turning off the N heaters when any of the first temperatures is determined to be higher than a second predefined temperature being higher than the first predefined temperature in the predefined time duration.

3. The method of claim 1, wherein the method further comprises:
turning off the N heaters when all of the second temperatures are determined to be higher than the first predefined temperature in the predefined time duration.

4. The method of claim 1, wherein the method further comprises:
generating and outputting a heating failure warning when the first temperature of at least one of the N first components is unchanged after the predefined time duration.

5. The method of claim 1, wherein the N heaters are turned on based on a predefined power.

6. The method of claim 3, wherein the method further comprises:
obtaining an environment temperature of the server and a heating temperature of each of the N heaters in real-time; and
generating and outputting a warning information when the environment temperature is higher than a third predefined temperature, and/or the heating temperature of any of the N heaters is higher than a fourth predefined temperature, and/or the first temperatures of all of the N first components is higher than a fifth predefined temperature;
wherein the third predefined temperature is higher than the first predefined temperature and is lower than the fourth predefined temperature; the fourth predefined temperature is higher than the second predefined temperature; the fifth predefined temperature is higher than the first predefined temperature and is lower than the third predefined temperature.

7. The method of claim 1, wherein the first component comprises at least one of a central processing unit (CPU), a Complex Programmable Logic Device (CPLD), a Platform Controller Hub (PCH), a Local Area Network (LAN) interface, and a Baseboard Management Controller (BMC).

8. A server comprises:
N first components;
N heaters;
M second components; and
a heating manager;
wherein N and M are integer larger than 1; each of the N heaters is disposed in one of the first components, a lowest starting temperature of each of the N first components is higher than a lowest starting temperature of each of the M second components;
wherein the heating manager is configured to obtain the first temperature of each first component and the second temperature of each second component, turn on the N heaters when at least one of the first temperatures and the second temperatures is determined to be less than a first predefined temperature, turn off the N heaters after the predefined time duration, and turn on the N first components and the M second components after the N heaters being turned off.

9. The server of claim 8, wherein the heating manager is further configured to turn off the N heaters when any of the first temperatures is determined to be higher than a second predefined temperature being higher than the first predefined temperature in the predefined time duration.

10. The server of claim 8, wherein the heating manager is further configured to turn off the N heaters when all of the second temperatures are determined to be higher than the first predefined temperature in the predefined time duration.

11. The server of claim 8, wherein the heating manager is further configured to generate and output a heating failure warning when the first temperature of at least one of the N first components is unchanged after the predefined time duration.

12. The server of claim 8, wherein the N heaters are turned on based on a predefined power.

13. The server of claim 8, wherein the heating manager is further configured to obtain an environment temperature of the server and a heating temperature of each of the N heaters in real-time, and generate and output a warning information when the environment temperature is higher than a third predefined temperature, and/or the heating temperature of any of the N heaters is higher than a fourth predefined temperature, and/or all the first temperatures of all of the N first components is higher than a fifth predefined temperature; wherein the third predefined temperature is higher than the first predefined temperature and is lower than the fourth predefined temperature; the fourth predefined temperature is higher than the second predefined temperature; the fifth predefined temperature is higher than the first predefined temperature and is lower than the third predefined temperature.

14. The server of claim 8, wherein the first component comprises at least one of a central processing unit (CPU), a Complex Programmable Logic Device (CPLD), a Platform Controller Hub (PCH), a Local Area Network (LAN) interface, and a Baseboard Management Controller (BMC).
